(19) United States
(12) Patent Application Publication
(10) Pub. No.: US 2026/0198275 A1
(43) Pub. Date: Jul. 9, 2026

(54) SELECTIVE HARD MASK ETCHING USING NON-PLASMA MICROWAVE PROCESSING

(71) Applicant: Applied Materials, Inc., Santa Clara, CA (US)

(72) Inventors: Mohammad Mahdi TAVAKOLI, Santa Clara, CA (US); Joung Joo LEE, San Jose, CA (US)

(21) Appl. No.: 19/013,229

(22) Filed: Jan. 8, 2025

(51) Int. Cl. H01L 21/768; H01L 21/311

(52) U.S. Cl. CPC H10W 20/033; H10P 50/283; H10W 20/056

(57) ABSTRACT

Embodiments of the present disclosure generally relate to non-plasma methods of processing a substrate. More specifically, the methods disclosed herein incorporate microwave oxidation that is used to selectively etch materials during semiconductor device manufacturing. The method for etching a semiconductor device structure is disclosed includes performing a microwave oxidation etch process on the semiconductor device structure, wherein a hard mask is disposed over at least a portion of the semiconductor device structure. The microwave oxidation etch process includes flowing a first process gas over the semiconductor device structure and delivering a microwave energy to the first process gas without generating a plasma. The method further includes performing a preclean process on the semiconductor device structure. The preclean process includes flowing a second process gas over the semiconductor device structure.

### BACKGROUND

### Field

Embodiments of the present disclosure generally relate to non-plasma methods of processing a substrate. More specifically, the methods disclosed herein incorporate microwave oxidation that is used to selectively etch materials during semiconductor device manufacturing.

### Description of the Related Art

Integrated circuits have evolved into complex devices that can include millions of transistors, capacitors, and resistors on a single chip. Examples of such a devices include memory (e.g., dynamic random access memory (DRAM)) and logic devices, including both planar and three-dimensional structures. Examples of three-dimensional structures are fin field-effect transistor (finFET) and metal-oxide-semiconductor field-effect transistor (MOSFET) devices. In the course of integrated circuit evolution, functional density (e.g., the number of interconnected devices per chip area) has generally increased while geometry size (e.g., the smallest component (or line) that can be created using a fabrication process) has decreased. Such geometry reduction has driven innovation into various etching processes to assist in the production of patterned devices.

In a traditional middle-of-the-line (MOL) interconnect formation process, a feature, such as a via or trench is fabricated in the semiconductor substrate. MOL contacts allow connections between front-end-of-the-line (FEOL) semiconductor structures and back-end-of-the-line (BEOL) interconnects. Contacts with low resistance are desirable in semiconductor devices. However, when a MOL interconnect has a relatively high resistance, a poor connection is created at the MOL interconnect, which reduces the overall performance of the packaged semiconductor structures.

Conventional MOL and BEOL electrical connections, such as contacts, interconnects, and the like, are formed by filling a feature such as a cavity, trench, or via with a conductive material. Then the feature is filled with a metal material to form a metal fill layer that serves as an interconnect between layers of the device. As devices reach the 1.4 nm node and beyond, molybdenum (Mo) is being used as the material of the metal fill layer or other layer components due to its lower resistivity inside smaller features. However, after additional MOL or BEOL processing is performed after depositing Mo process gases such as nitrogen or ammonia (NH₃), or the gases in the ambient environment, such as O₂ or H₂O, cause nitridation and oxidation of the surfaces of the formed Mo metal fill layer and significantly increase the resistance of the formed interconnect due to the presence of nitrogen or oxygen containing layers formed on exposed surfaces. Further, additional layers of conductive metals such as Tungsten carbide (WC) may be disposed over the via. An etch process is needed to remove at least the unwanted portions of the nitridation or oxidation layer and at least a portion of the additional conductive metal layers.

Dry etch processes are often desirable for selectively removing material from semiconductor substrates, as these processes are capable of gently removing material from miniature structures with minimal physical disturbance. Additionally, dry etch processes have been developed to selectively remove/etch a variety of dielectrics relative to one another. However, such dry etch processes often incorporate the generation of a plasma and/or are conducted at high temperatures in the presence of halogenated process gases. Such process conditions can unintentionally and/or undesirably damage underlying layers of the semiconductor substrate.

Therefore, there is a need to develop new etch processes that can selectively remove materials and minimize the amount of damage to the remaining portions of features that are exposed during the etching process.

### SUMMARY

In a first embodiment, a method for etching a semiconductor device structure is disclosed. The method includes performing a microwave oxidation etch process on the semiconductor device structure, wherein a hard mask is disposed over at least a portion of the semiconductor device structure. The microwave oxidation etch process includes flowing a first process gas over the semiconductor device structure and delivering a microwave energy to the first process gas without generating a plasma. The method further includes performing a preclean process on the semiconductor device structure. The preclean process includes flowing a second process gas over the semiconductor device structure.

In another embodiment, a method of filling a semiconductor device structure, is disclosed. The method includes performing a microwave oxidation etch process on the semiconductor device structure, wherein the microwave oxidation process includes flowing a first process gas over the semiconductor device structure, and delivering a microwave energy to the first process gas without generating a plasma. The semiconductor device structure includes a substrate, at least one dielectric layer, where at least one feature is patterned in the at least one dielectric layer, the at least one feature comprising an upper surface, a plurality of sidewall surfaces, and a bottom surface, an etch stop layer disposed between the substrate and the at least one dielectric layer, a metal layer disposed within the at least one feature, a hard mask disposed over at least the upper surface of the feature, and a metal oxide layer disposed over the bottom surface of the feature. The method further includes performing a preclean process on the semiconductor device structure, the preclean process including flowing a second process gas over the at least one feature. The method further includes performing a selective deposition of a capping layer within the at least one feature, the capping layer disposed over the metal layer.

In another embodiment, a method of filling a semiconductor device structure is disclosed. The method includes performing a microwave oxidation etch process on the semiconductor device structure comprising at least one feature formed in a dielectric layer of the semiconductor device structure, wherein a hard mask is disposed over at least a portion of the semiconductor device structure, the microwave oxidation etch process includes flowing a first process gas over the at least one feature, and delivering a microwave energy to the first process gas without generating a plasma. The method further includes performing a preclean process on the semiconductor device structure, the preclean process includes flowing a second process gas over the at least one feature. The method further includes performing a selective deposition of a capping layer, the capping layer disposed within the at least one feature. The method further includes depositing a metal fill material over the capping layer to fill the at least one feature.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments of the disclosure and are therefore not to be considered limiting of its scope, as the disclosure may admit to other equally effective embodiments.

FIG. 1 illustrates a schematic top view of a multi-chamber processing system, according to one or more embodiments.

FIG. 2A is a schematic of a processing chamber that includes a microwave source, according to one or more embodiments.

FIG. 2B is a schematic of a solid state microwave emission module, according to one or more embodiments.

FIG. 2C is a perspective view illustration of a source array for a microwave source, according to one or more embodiments.

FIG. 2D is a cross-sectional illustration of a processing chamber for processing a substrate, according to one or more embodiments.

FIG. 3 is a flow diagram that depicts a method of processing a substrate, according to one or more embodiments.

FIGS. 4A, 4B, 4C, 4D, and 4E illustrate views of various stages of forming an electrical connection of a semiconductor structure, according to one or more embodiments.

FIG. 5 illustrates the impact of microwave oxidation on a hard mask at varying conditions.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to non-plasma methods of processing a substrate. More specifically, the methods disclosed herein incorporate microwave oxidation that is used to selectively etch materials during semiconductor device manufacturing. Middle-of-the-line (MOL) and back-end-of-the-line (BEOL) electrical connections, such as interconnects, and the like are formed by filling a feature such as a cavity, trench, or via with a conductive material that is in contact with an underlying metal layer, the conductive material is a metal fill material. During processing, a hard mask such as a tungsten carbide (WC) hard mask forms over the feature. For example, a layer of WC hard mask may form over the upper surface of the dielectric layer. During further processing, selective molybdenum (Mo) deposition occurs to at least partially fill a portion of the feature, the selective Mo deposition forms a layer over the WC hard mask. A selective etching process, which utilizes microwave enhanced non-plasma processing methods, is used to remove the WC hard mask before further processing. The methods disclosed herein may include positioning a substrate into a processing chamber, flowing a process gas into the processing chamber, and delivering an amount of microwave energy at a microwave frequency to the process gas to perform an etch operation on the substrate without generating a plasma. The lack of plasma generation allows for compositionally selective etching without the potential to damage underlying films or the feature. Once the WC hard mask is removed from the feature, the selective deposition of Mo deposits a layer of Mo along the bottom of the feature. The selective deposition results in a rounded layer shape (e.g., a semicircle or a bump). After the selective deposition of Mo, further processing is conducted to complete the interconnect.

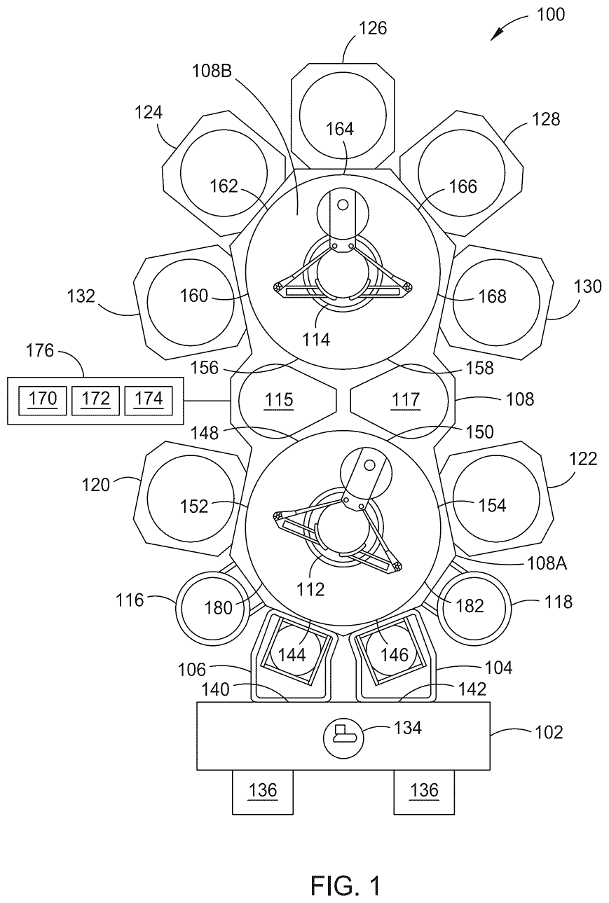

FIG. 1 illustrates a schematic top view of a multi-chamber processing system 100 according to one or more embodiments. The multi-chamber processing system 100 can be used for creating a bottom lateral recess (an etch recess) in a device substrate to anchor a metal material of an MOL or BEOL electrical connection during a chemical mechanical polishing (CMP) process. As detailed below, substrates in the processing system 100 may be processed in and transferred between the various chambers without exposing the substrates to an ambient environment exterior to the processing system 100 (for example, an atmospheric ambient environment may be present in a fab). For example, the substrates may be processed in and transferred between the various chambers maintained at a low pressure (for example, less than or equal to about 300 Torr) or sub-atmospheric pressure, such as a vacuum environment, without breaking the reduced relative pressure or vacuum environment among various processes performed on the substrates in the processing system 100. Accordingly, the processing system 100 may provide for an integrated solution for some processing of substrates.

The multi-chamber processing system 100 generally includes a factory interface 102, load lock chambers 104, 106, a transfer chamber 108 (with a first portion 108A and a second portion 108B) with respective transfer robots 112, 114, holding chambers 115, 117, one or more optional service chambers 116, 118, and processing chambers 120, 122, 124, 126, 128, 130, 132. In one or more embodiments, the first portion 108A of the transfer chamber 108 and the second portion 108B of the transfer chamber 108 are separate transfer chambers. As detailed herein, substrates in the multi-chamber processing system 100 can be processed in and transferred between the various chambers without exposing the substrates to an ambient environment exterior to the multi-chamber processing system 100, for example, an atmospheric ambient environment such as may be present in a fab. The substrates can be processed in and transferred between the various chambers maintained at a low pressure, for example, less than or equal to about 300 Torr, or a vacuum environment without breaking the low pressure or vacuum environment among various processes performed on the substrates in the multi-chamber processing system 100. Accordingly, the multi-chamber processing system 100 may provide for an integrated solution for processing of substrates.

Examples of multi-chamber processing systems that may be suitably modified in accordance with the teachings provided herein include the Endura®, Producer®, or Centura® integrated multi-chamber processing systems or other suitable multi-chamber processing systems commercially available from Applied Materials, Inc., located in Santa Clara, California. It is contemplated that other multi-chamber processing systems (including those from other manufacturers) may be adapted to benefit from aspects described herein.

In the illustrated example of FIG. 1, the factory interface 102 includes a docking station and at least one factory interface robot 134 to facilitate transfer of substrates. The docking station is adapted to accept one or more front opening unified pods (FOUPs) 136. In some examples, each factory interface robot 134 generally includes a blade disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The first portion 108A of the transfer chamber 108 further has respective ports 148, 150 coupled to the holding chambers 115, 117, respective ports 180,182 coupled to one or more optional service chambers 116, 118, and respective ports 152, 154 coupled to processing chambers 120, 122. Similarly, the second portion 108B of the transfer chamber 108 has respective ports 156, 158 coupled to the holding chambers 115, 117 and respective ports 160, 162, 164, 166 coupled to processing chambers 124, 126, 128, 130, 132. The ports 144, 146, 148, 150, 152, 154, 156, 158, 160, 162, 164, 166, 180, 182 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, the transfer chamber 108, the holding chambers 115, 117, one or more optional service chambers 116, 118, and the processing chambers 120, 122, 124, 126, 128, 130, 132 may be fluidly coupled to a gas and pressure control system (not specifically illustrated). The gas and pressure control system can include one or more gas pumps (for example, turbo pumps, cryo-pumps, roughing pumps) gas sources, various valves, and conduits fluidly coupled to the various chambers. In operation, the factory interface robot 134 transfers a substrate from the FOUP 136 through the port 140 or 142 to the load lock chamber 104 or 106. The gas and pressure control system then pumps down the load lock chamber 104 or 106. The gas and pressure control system further maintains the transfer chamber 108 and the holding chambers 115, 117 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108. In some embodiments, one or more optional service chambers (shown as 116 and 118) may be coupled to the transfer chamber 108. The service chambers 116 and 118 may be configured to perform other substrate processes, such as degassing, orientation, substrate metrology, cool down, and the like.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing, the one or more optional service chambers 116, 118 through the respective ports 180, 182, and the holding chambers 115, 117 through the respective ports 148, 150 for holding to await further transfer. Similarly, the transfer robot 114 is capable of accessing the substrate in the holding chamber 115 or 117 through the port 156 or 158 and is capable of transferring the substrate to and/or between any of the processing chambers 124, 126, 128, 130, 132 through the respective ports 160, 162, 164, 166, 168 for processing and the holding chambers 115, 117 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130, 132 can be any appropriate chamber for processing a substrate. In some examples, the processing chamber 120 can be capable of performing an etch process, the processing chamber 122 can be capable of performing a cleaning process, and the processing chambers 126, 128, 130, 132 can be capable of performing respective growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 124, 126, 128, 130, or 132 may be a Volta™ CVD/ALD chamber, Trillium™ ALD chamber, or Encore™ PVD chambers available from Applied Materials of Santa Clara, Calif.

A system controller 176 is coupled to the multi-chamber processing system 100 for controlling the multi-chamber processing system 100 or components thereof. For example, the system controller 176 may control the operation of the multi-chamber processing system 100 using a direct control of the chambers 104, 106, 108, 115, 116, 117, 118, 120, 122, 124, 126, 128, 130, 132 of the multi-chamber processing system 100 or by controlling controllers associated with the chambers 104, 106, 108, 115, 116, 117, 118, 120, 122, 124, 126, 128, 130, 132. In operation, the system controller 176 enables data collection and feedback from the respective chambers to coordinate performance of the multi-chamber processing system 100.

The system controller 176 generally includes a central processing unit (CPU) 170, memory 172, and support circuits 174. The CPU 170 may be one of any form of a general-purpose processor that can be used in an industrial setting. The memory 172, non-transitory computer-readable medium, or machine-readable storage device, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. That is, the computer program product is tangibly embodied on the memory 172 (or non-transitory computer-readable medium or machine-readable storage device). When the computer instruction code is executed by the CPU 170, the CPU 170 controls the chambers to perform processes in accordance with the various methods.

The instructions in memory 172 may be in the form of a program product, such as a program that implements the methods of the present disclosure. In one example, the disclosure may be implemented as a program product stored on a computer-readable storage media for use with a computer system. The program(s) of the program product define functions of the implementations (including the methods described herein). Thus, the computer-readable storage media, when carrying computer-readable instructions that direct the functions of the methods described herein, are implementations of the present disclosure. The system controller 176 is configured to perform methods such as the method 300 stored in the memory 172.

As will be described further below, in one or more embodiments of the substrate processing sequence described herein, all of the processes are performed under vacuum within the processing system 100. In one example of the processing system 100, a remote-plasma-source (RPS) cleaning process is performed in chamber 122, a precleaning process is performed in chamber 120, and one or more of a deposition, an etching, and/or a thermal processing process is performed in at least one of the chambers 132, 124, 126, 128, and 130. In one example, the remote plasma (RPS) assisted process performed in chamber 122 is performed in a processing chamber, such as Aktiv™ Preclean (APC) chamber available from Applied Materials of Santa Clara, Calif. In another example, the processing chambers 132, 124, 126, 128, or 130 may be a Volta™ CVD/ALD chamber, or Encore™ PVD chambers available from Applied Materials of Santa Clara, Calif.

In another example of the processing system 100, a remote-plasma-source (RPS) cleaning process and a precleaning process are both performed in at least one of the chambers 122 and 120, and one or more of a deposition, an etching, and/or a thermal processing process is performed in at least one of the chambers 132, 124, 126, 128, and 130. In one example, the processing chambers 132, 124, 126, 128, or 130 may be a Volta™ CVD/ALD chamber, or Encore™ PVD chambers available from Applied Materials of Santa Clara, Calif.

Other processing systems can be in other configurations. For example, more or fewer processing chambers may be coupled to a transfer apparatus. In the illustrated example, the transfer apparatus includes the transfer chambers 108 and the holding chambers 115, 117. In other examples, more or fewer transfer chambers (e.g., one transfer chamber) and/or more or fewer holding chambers (e.g., no holding chambers) may be implemented as a transfer apparatus in a processing system.

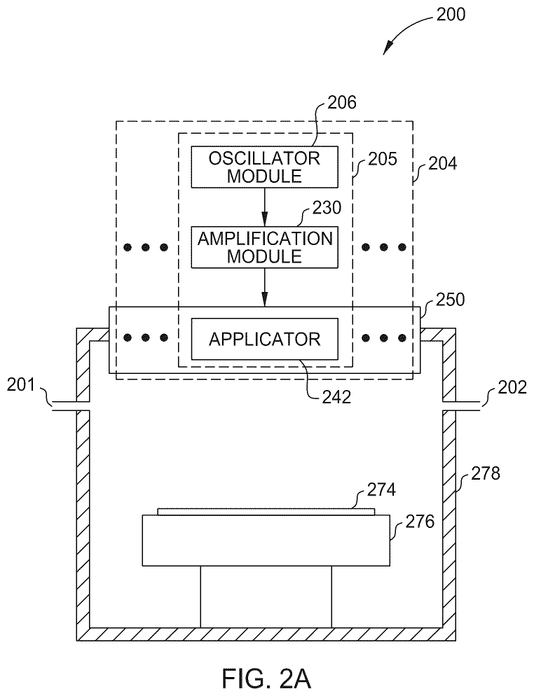

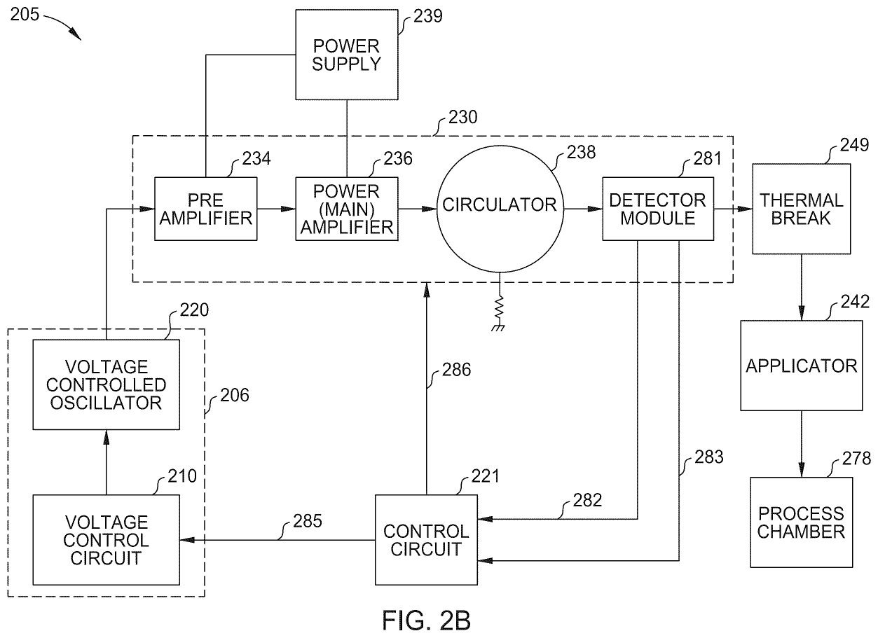

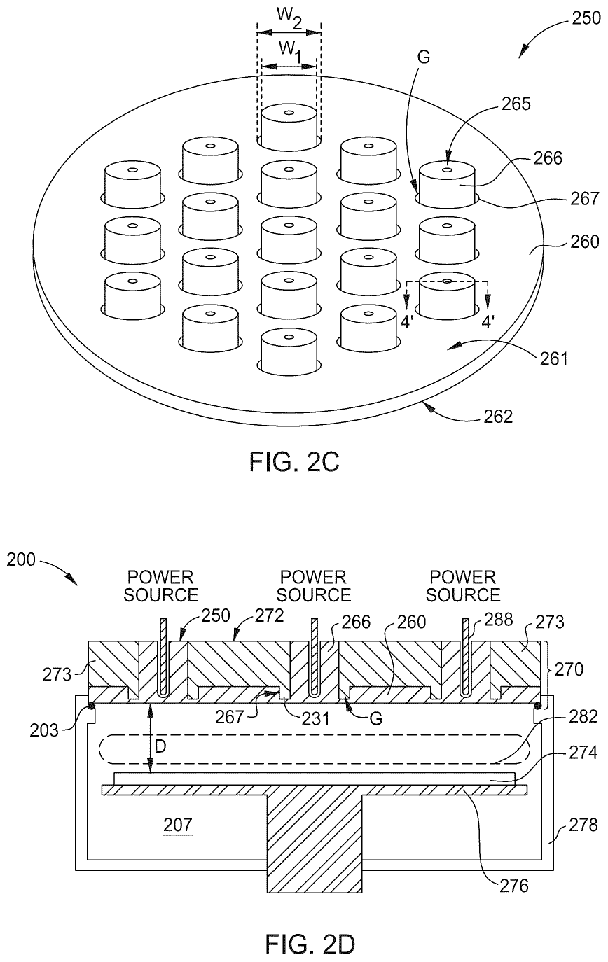

FIGS. 2A and 2B depict an example of a microwave processing tool 200. The microwave processing tool 200 is configured to deliver microwave energy to a processing region of the process chamber to perform a selective etching process on a substrate, which can be performed at a desired processing temperature.

FIG. 2A is a cross-sectional illustration of a microwave processing tool 200 (referred to as processing tool 200 for short). In some embodiments, the processing tool 200 may be a processing tool suitable for any type of processing operation that requires the delivery of microwave energy. In some embodiments, one or more of the chambers 120 and 122, or even chambers 132-140, may include the processing tool 200. The processing tool may emit high-frequency electromagnetic radiation in the form of microwave energy. In some embodiments, “High-frequency” may refer to frequencies between 300 MHz and 1000 GHz. In some embodiments, the high-frequency electromagnetic radiation is provided at frequencies in the “S-band”, such as frequencies between about 2.4 GHz and about 2.6 GHz.

Generally, embodiments include a processing tool 200 that includes a chamber 278. In processing tool 200, the chamber 278 may be a vacuum chamber. A vacuum chamber may include a pump (not shown) for removing gases from the chamber to provide the desired vacuum. Additional embodiments may include a chamber 278 that includes one or more gas lines 201 for providing processing gases into the chamber 278 and exhaust lines 202 for removing byproducts from the chamber 278. While not shown, it is to be appreciated that gas may also be injected into the chamber 278 through a source array 250 (e.g., as a showerhead) for evenly distributing the processing gases over a substrate 274.

In an embodiment, the substrate 274 may be supported on a chuck 276. For example, the chuck 276 may be any suitable chuck, such as an electrostatic chuck. The chuck 276 may also include cooling lines and/or a heater to provide temperature control to the substrate 274 during processing. Due to the modular configuration of the high-frequency emission modules described herein, embodiments allow for the processing tool 200 to accommodate any sized substrate 274. For example, the substrate 274 may be a semiconductor wafer (e.g., 200 mm, 300 mm, 450 mm, or larger). Alternative embodiments also include substrates 274 other than semiconductor wafers. For example, embodiments may include a processing tool 200 configured for processing glass substrates, (e.g., for display technologies).

According to an embodiment, the processing tool 200 includes a modular high-frequency emission source 204. The modular high-frequency emission source 204 may comprise an array of solid state high-frequency emission modules 205. In an embodiment, each solid state high-frequency emission module 205 may include an oscillator module 206, an amplification module 230, and an applicator 242. As shown, the applicators 242 are schematically shown as being integrated into the source array 250.

In an embodiment, the oscillator module 206 and the amplification module 230 may comprise electrical components that are solid state electrical components. In an embodiment, each of the plurality of oscillator modules 206 may be communicatively coupled to different amplification modules 230. For example, each oscillator module 206 may be electrically coupled to a single amplification module 230. In an embodiment, the plurality of oscillator modules 206 may generate incoherent electromagnetic radiation. Accordingly, the electromagnetic radiation induced in the chamber 278 will not interact in a manner that results in an undesirable interference pattern.

In an embodiment, each oscillator module 206 generates high frequency electromagnetic radiation that is transmitted to the amplification module 230. After processing by the amplification module 230, the electromagnetic radiation is transmitted to the applicator 242. In an embodiment, the applicators 242 each emit electromagnetic radiation into the chamber 278. In some embodiments, the applicators 242 couple the electromagnetic radiation to the processing gases in the chamber 278 to provide energy thereto, without forming a plasma.

FIG. 2B is a schematic of a solid state high-frequency emission module 205. In an embodiment, the solid state high-frequency emission module 205 comprises an oscillator module 206. The oscillator module 206 may include a voltage control circuit 210 for providing an input voltage to a voltage controlled oscillator 220 in order to produce high-frequency electromagnetic radiation at a desired frequency. The voltage controlled oscillator 220 is an electronic oscillator whose oscillation frequency is controlled by the input voltage. According to an embodiment, the input voltage from the voltage control circuit 210 results in the voltage controlled oscillator 220 oscillating at a desired frequency.

According to an embodiment, the electromagnetic radiation is transmitted from the voltage controlled oscillator 220 to an amplification module 230. The amplification module 230 may include a driver/pre-amplifier 234, and a main power amplifier 236 that are each coupled to a power supply 239. According to an embodiment, the amplification module 230 may operate in a pulse mode. For example, the amplification module 230 may have a duty cycle between 1% and 99%. In a more particular embodiment, the amplification module 230 may have a duty cycle between approximately 15% and 50%.

In an embodiment, the electromagnetic radiation may be transmitted to the thermal break 249 and the applicator 242 after being processed by the amplification module 230. However, part of the power transmitted to the thermal break 249 may be reflected back due to the mismatch in the output impedance. Accordingly, some embodiments include a detector module 281 that allows for the level of forward power 283 and reflected power 282 to be sensed and fed back to the control circuit module 221. It is to be appreciated that the detector module 281 may be located at one or more different locations in the system (e.g., between the circulator 238 and the thermal break 249). In an embodiment, the control circuit module 221 interprets the forward power 283 and the reflected power 282, and determines the level for the control signal 285 that is communicatively coupled to the oscillator module 206 and the level for the control signal 286 that is communicatively coupled to the amplification module 230. In an embodiment, control signal 285 adjusts the oscillator module 206 to optimize the high-frequency radiation coupled to the amplification module 230. In an embodiment, control signal 286 adjusts the amplification module 230 to optimize the output power coupled to the applicator 242 through the thermal break 249. In an embodiment, the feedback control of the oscillator module 206 and the amplification module 230, in addition to the tailoring of the impedance matching in the thermal break 249, may allow for the level of the reflected power to be less than approximately 5% of the forward power. In some embodiments, the feedback control of the oscillator module 206 and the amplification module 230 may allow for the level of the reflected power to be less than approximately 2% of the forward power.

Accordingly, embodiments allow for an increased percentage of the forward power to be coupled into the processing chamber 278, and increases the available power provided to the process gases disposed within the processing volume. Furthermore, impedance tuning using a feedback control is superior to impedance tuning in typical slot-plate antennas. In slot-plate antennas, the impedance tuning involves moving two dielectric slugs formed in the applicator. This involves mechanical motion of two separate components in the applicator, which increases the complexity of the applicator.

Referring now to FIG. 2C, a perspective view illustration of a source array 250 is shown, in accordance with an embodiment. In an embodiment, the source array 250 comprises a dielectric plate 260. A plurality of cavities 267 are disposed into a first surface 261 of the dielectric plate 260. The cavities 267 do not pass through to a second surface 262 of the dielectric plate 260. The source array 250 may further include a plurality of dielectric resonators 266. Each of the dielectric resonators 266 may be in a different one of the cavities 267. Each of the dielectric resonators 266 may comprise a hole 265 in the axial center of the dielectric resonator 266.

In an embodiment, the dielectric resonators 266 may have a first width W1, and the cavities 267 may have a second width W2. The first width W1 of the dielectric resonator 266 is smaller than the second width W2 of the cavities 267. The difference in the widths provides a gap G between a sidewall of the dielectric resonators 266 and a sidewall of the cavity 267. In the illustrated embodiment, each of the dielectric resonators 266 are shown as having a uniform width W1. However, it is to be appreciated that not all dielectric resonators 266 of a source array 250 need to have the same dimensions.

Referring now to FIG. 2D, a cross-sectional illustration of a processing tool 200 that includes an assembly 270 is shown, in accordance with an embodiment. In an embodiment, the processing tool comprises a chamber 278 that is sealed by an assembly 270. For example, the assembly 270 may rest against one or more O-rings 203 to provide a vacuum seal to an interior chamber volume 207 of the chamber 278. In other embodiments, the assembly 270 may interface with the chamber 278. That is, the assembly 270 may be part of a lid that seals the chamber 278. In an embodiment, the processing tool 200 may comprise a plurality of processing volumes (which may be fluidically coupled together), with each processing volume having a different assembly 270. In an embodiment, a chuck 276 or the like may support a substrate 274. The substrate 274 may be a distance D from the assembly 270. In an embodiment, the interior chamber volume 207 may be suitable for delivering microwave energy to a process gas disposed within the chamber 278. That is, the chamber 278 may be a vacuum chamber.

In an embodiment, the assembly 270 comprises a source array 250 and a housing 272. The source array 250 may comprise a dielectric plate 260 and a plurality of dielectric resonators 266 extending up from the dielectric plate 260. Cavities 267 into the dielectric plate 260 may surround each of the dielectric resonators 266. Sidewalls of the cavity 267 are separated from the sidewall of the dielectric resonator 266 by a gap G. The dielectric plate 260 and the dielectric resonators 266 of the source array 250 may be a monolithic structure (as shown in FIG. 2D), or the dielectric plate 260 and the dielectric resonators 266 may be discrete components.

The housing 272 includes rings 231 that fit into the gaps G. In an embodiment, the rings 231 and the conductive body 273 of the housing 272 are a monolithic structure (as shown in FIG. 2D), or the conductive body 273 and the rings 231 may be discrete components. The housing 272 may having openings sized to receive the dielectric resonators 266. In an embodiment, monopole antennas 288 may extend into holes in the dielectric resonators 266. The monopole antennas 288 are each electrically coupled to power sources (e.g., solid state high-frequency emission modules 205).

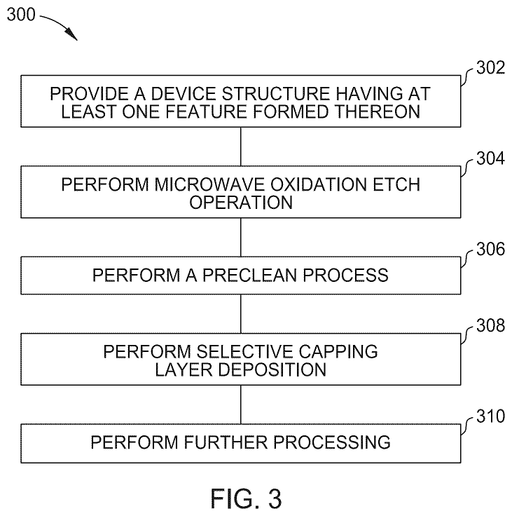

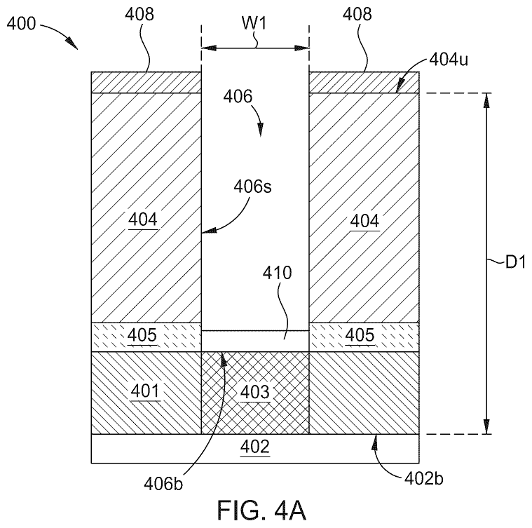

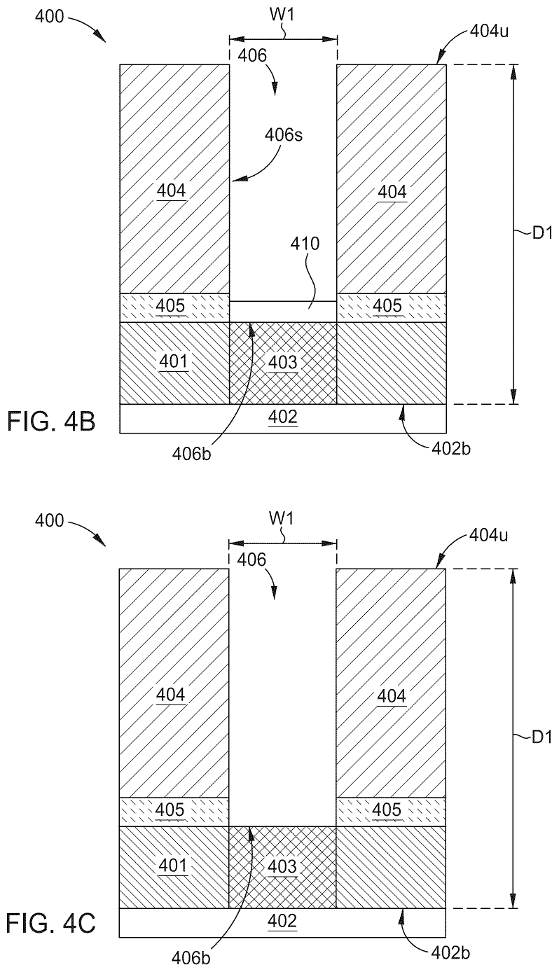

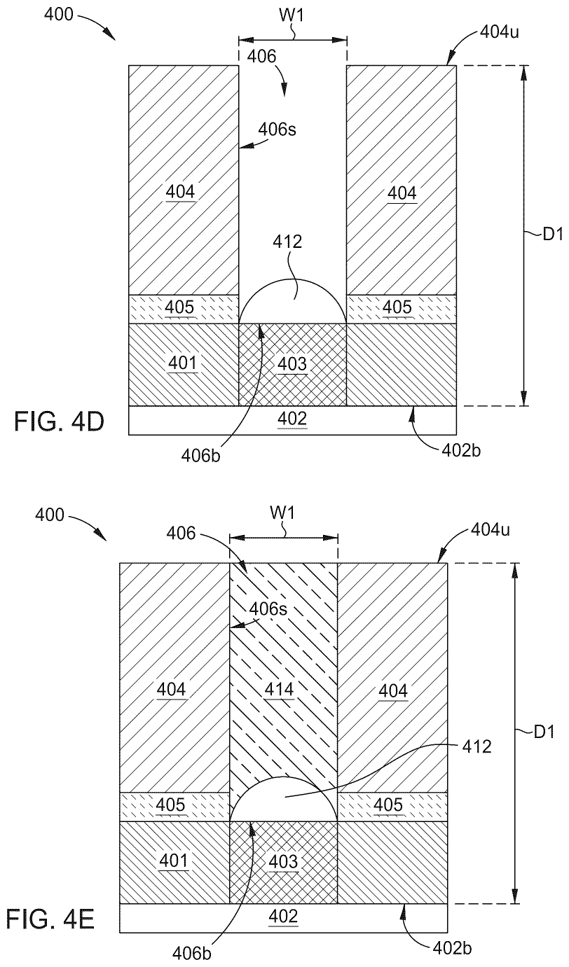

FIG. 3 is a flow diagram depicting a method of processing a substrate to form, for example, middle-of-line (MOL) and back-end-of-line (BEOL) structures. FIGS. 4A, 4B, 4C, 4D, and 4E are cross-sectional views of various stages of forming an electrical connection of a semiconductor structure (e.g., a feature on a substrate). FIGS. 4A-4E are only partial schematic views of the semiconductor device structure 400, and the semiconductor device structure 400 may contain any number of transistor sections and additional materials having aspects as illustrated in the figures. It should also be noted that although the method illustrated in FIG. 3 is described sequentially, other process sequences that include one or more operations that have been omitted and/or added, and/or has been rearranged in another desirable order, fall within the scope of the embodiments of the disclosure provided herein. Method 300 may be performed in a processing chamber (e.g., processing chambers 120, 122, 124, 126, 128, 130, or 132), as shown in FIG. 1.

As shown in FIG. 4A, at operation 302, a semiconductor device structure 400 having at least one feature thereon is provided. The semiconductor device structure 400 includes a device substrate 402 having one or more layers formed thereon, for example, dielectric layers 401 and 404, underlying metal layer 403, and etch stop layer 405 as is shown in FIG. 4A. The device substrate 402 may be or include a bulk semiconductor substrate, a semiconductor-on-insulator (SOI) substrate, or the like, which may be doped (e.g., with a p-type dopant or an n-type dopant) or undoped. In some embodiments, the semiconductor material of the base substrate portion of the device substrate 402 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AlInAs, GaInAs, GaInP, and/or GaInAsP; a combination thereof, or the like. The device substrate 402 may include additional materials, for example, silicide layers, metal silicide layers, metal layers, dielectric layers, etch stop layers, interlayer dielectrics, or a combination thereof.

The device substrate 402 may further include integrated circuit devices (not shown) that are formed in one or more layers below the layers shown in FIGS. 4A-4E. As one of ordinary skill in the art will recognize, a wide variety of integrated circuit devices such as transistors, diodes, capacitors, resistors, the like, or combinations thereof may be formed in and/or on the device substrate 402 to generate the structural and functional requirements of the design for the resulting semiconductor device structure 400.

The dielectric layers 401 and 404, and the etch stop layer 405 are formed over the device substrate 402. In one or more embodiments, the etch stop layer 405 is formed between dielectric layer 401 and dielectric layer 404. The dielectric layer 401 is formed over the device substrate 402 (and the additional layers formed over the device substrate (if any)), the etch stop layer 405 is formed over the dielectric layer 401, and the dielectric layer 404 is formed over the etch stop layer 405. The etch stop layer 405 is disposed between the dielectric layers 401 and 404.

The dielectric layers 401 and 404 may include multiple layers. The dielectric layer 404 includes an upper surface 404u or field region. In some embodiments, the dielectric layers 401 and 404 include a dielectric material, such as a low k dielectric (SiCOH), silicon oxide, silicon dioxide (SiO₂), silicon nitride (Si₃N₄), silicon carbide (SiC), silicon oxynitride (SiON), aluminum oxide (Al₂O₃), aluminum nitride (AlN), a combination thereof, or multi-layers thereof. In some embodiments, the dielectric layers 401 and 404 consist essentially of silicon oxide. It is noted that the foregoing descriptors for example, silicon oxide, should not be interpreted to disclose any particular stoichiometric ratio. Accordingly, “silicon oxide” and the like will be understood by one skilled in the art as a material consisting essentially of silicon and oxygen without disclosing any specific stoichiometric ratio. In one or more embodiments, the etch stop layer 405 includes any suitable material including, but not limited to, silicon nitride, silicon carbide, metal oxide, or carbon containing, or combinations thereof.

The semiconductor device structure 400 is patterned to form one or more feature(s) 406. The feature 406 may be a high aspect ratio (HAR) feature. In some embodiments, the feature 406 can be selected from, but not limited to, a trench, a via, a hole, a cavity, or a combination thereof. In particular embodiments, the feature 406 is a trench. In other particular embodiments, the feature 406 is a via. In some embodiments, the feature 406 extends from the upper surface 404u of the dielectric layer 404 towards the backside 402b of the device substrate 402. The feature 406 includes sidewall surface(s) 406s that extend from the upper surface 404u to the backside 402b.

In some embodiments, an electrical connection (not shown) is formed within the dielectric layer 401 formed at the bottom of the feature 406. The electrical connection may be an interconnect, a contact structure, or the like that includes the conductive material found in the underlying metal layer 403. The electrical connection is formed in a prior patterning sequence performed prior to forming the dielectric layer 404 and forming feature 406 therein. For example, as shown in FIG. 4A, the electrical connection may be a contact structure that includes a conductive material. The conductive material may be formed of copper (Cu), cobalt (Co), molybdenum (Mo), tungsten (W), tantalum (Ta), titanium (Ti), or ruthenium (Ru), combinations thereof, and/or nitrides thereof. The feature 406 has a first depth “D1” from the upper surface 404u to the backside 402b and a width “W1” between the two sidewall surface(s) 406s. In some embodiments, the depth D1 is in a range of 2 nm to 200 nm. In some embodiments, the width W1 is in a range of 10 nm to 100 nm. In some embodiments, the feature 406 has an aspect ratio (D/W) in a range of 1 to 20.

In some embodiments, as shown in FIG. 4A, the semiconductor device structure 400 may have a metal oxide layer 410, a hard mask 408, or other contaminants formed on the sidewall surface(s) 406s, the underlying metal layer 403, the upper surface 404u, and/or the bottom surface 406b.

In one example, the metal oxide layer 410 is tungsten oxide, titanium nitride, titanium silicide, molybdenum oxide, or aluminum oxide. The semiconductor device structure 400 may be exposed to atmosphere prior to or during processing, which may lead to the formation of the metal oxide layer 410 on the surfaces of the feature 406. For example, if a vacuum break occurs prior to or during the method 300, the vacuum break can lead to the formation of native oxides. In addition, other processes performed prior to or during the method 300 may lead to the formation of additional contaminants or debris on the sidewall surface(s) 406s, the upper surface 404u, and the underlying metal layer 403. In other embodiments, the metal oxide layer 410 may not be present on the surfaces of the feature 406 and underlying metal layer 403. In one example, processes performed prior to or during method 300 may lead to the formation of additional contaminants, debris or layers such as a hard mask 408 on the upper surface 404u. For example, the hard mask 408 includes a tungsten carbide (WC). In one or more embodiments, physical vapor deposition (PVD) and/or sputtering methods are used to deposit hard masks (e.g., a tungsten carbide hard mask) over a feature 406.

At operation 304, as shown in FIG. 4B, a microwave oxidation etch process is performed on the semiconductor device structure 400. The microwave oxidation etch process includes flowing a process gas into the process chamber and delivering a microwave energy to the flowing process gas to perform an etch operation on the substrate. In one example, the process gas is oxygen (O₂). The microwave oxidation etch process of operation 304 is selective because the process gas is consumed by the etching process. The process gas used during the microwave oxidation etch process does not etch other components of the semiconductor device structure 400 (e.g., the microwave oxidation etch process is operated in a “starvation mode” such that the process gas is consumed before it etches additional layers of the semiconductor device structure 400). In one or more embodiments, the microwave oxidation etch process is a gradient etch process.

In some embodiments, operation 304 may include pulsing the delivery of the microwave energy in a sequence that has a duty cycle of between 1% and 99%, such as between 20% and 80%. The pulsing process is performed while the process gas is flowing and until the selective etching process removes a desired amount of material from the substrate. The processes performed during operation 304 includes the delivery of the microwave energy at a power level that does not generate a plasma in the processing region over the surface of the substrate, which can be verified by use of various metrology techniques that can include the use of a Langmuir probe or optical detection technique. Substrates of the present disclosure may include one or more layers and/or features formed from one or more dielectric, gapfill, or hard mask materials.

The process gas may include one or more oxygen based process gases, such as O₂ gas, ozone, and combinations thereof. In at least one embodiment, the process gas is O₂ gas. The process gas may be flowed into the processing chamber at a flow rate of about 1 sccm to about 100 sccm, such as about 2.5 sccm to about 50 sccm, such as about 5 sccm to about 25 sccm, alternatively about 1 sccm to about 2.5 sccm, alternatively about 2.5 sccm to about 5 sccm, alternatively about 5 sccm to about 10 sccm, alternatively about 10 sccm to about 25 sccm, alternatively about 25 sccm to about 50 sccm, alternatively about 50 sccm to about 100 sccm.

The etch operation of operation 304 may be conducted without generating a plasma. In some embodiments, the lack of generated electromagnetic radiation at frequencies not provided to the processing region of the process chamber, such as wavelengths in the visible region, can be used to detect that a plasma has not been formed within the processing region. In at least one embodiment, the temperature within the processing chamber during operation 304 may be maintained at about 0° C. to about 500° C., such as about 10° C. to about 400° C., such as about 20° C. to about 350° C., alternatively about 100° C. to about 200° C., alternatively about 200° C. to about 250° C., alternatively about 250° C. to about 300° C., alternatively about 300° C. to about 350° C., alternatively about 350° C. to about 400° C., alternatively about 400° C. to about 500° C. In at least one embodiment, the pressure within the processing chamber during operation 304 is about 1 mTorr to about 100 Torr, such as about 10 mTorr to about 1 Torr, such as about 20 mTorr to about 100 mTorr, such as about 40 mTorr to about 80 mTorr, alternatively about 40 mTorr to about 60 mTorr, alternatively about 20 mTorr to about 40 mTorr, alternatively about 40 mTorr to about 50 mTorr, alternatively about 50 mTorr to about 60 mTorr, alternatively about 60 mTorr to about 80 mTorr, alternatively about 80 mTorr to about 100 mTorr.

In at least one embodiment, the microwave energy applied to the process gas during operation 304 is about 25 W to about 300 W, such as about 50 W to about 250 W, such as about 100 W to about 200 W, alternatively about 25 W to about 50 W, alternatively about 50 W to about 100 W, alternatively about 100 W to about 150 W, alternatively about 150 W to about 200 W, alternatively about 200 W to about 250 W, alternatively about 250 W to about 300 W, alternatively about 50 W to about 150 W. In some embodiments, the microwave energy is provided at frequencies in the “S-band”, such as frequencies between about 2.4 GHz and about 2.6 GHz, such as about 2.45 GHz. The microwave energy may be applied to the process gas for about 1 min to about 10 min, such as about 2 min to about 8 min, such as about 4 min to about 6 min, alternatively about 1 min to about 2 min, alternatively about 2 min to about 4 min, alternatively about 4 min to about 5 min, alternatively about 5 min to about 6 min, alternatively about 6 min to about 8 min, alternatively about 8 min to about 10 min, alternatively about 2 min to about 5 min.

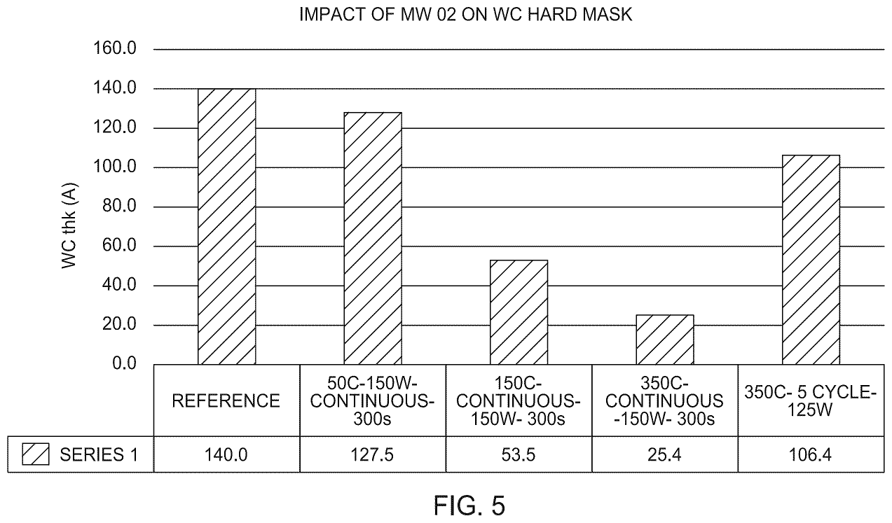

In one or more embodiments, varying the parameters of the microwave oxidation etch process etches the hard mask 408 at different rates. As shown in FIG. 5, the thickness of the hard mask 408 including WC is measured after varying parameters of the etch process seen in operation 304. As shown in FIG. 5, the reference sample includes a hard mask thickness of 140 angstroms (Å). In one example, the parameters of 50 ° C., 150 W, a pressure for about 2 mTorr to about 20 mTorr, and a continuous flow for 300 seconds results in a hard mask thickness of 127.5 Å. In another example, the parameters of 150° C., 150 W, a pressure for about 2 mTorr to about 20 mTorr, and a continuous flow for 300 seconds results in a hard mask thickness of 53.5 Å. In another example, 350° C., 150 W, a pressure for about 2 mTorr to about 20 mTorr, and a continuous flow for 300 seconds results in a hard mask thickness of 25.4 Å. In another example, the parameters of 350° C., 125 W, a pressure for about 2 mTorr to about 20 mTorr, and a pulsed cycle (where deposition was “on” for 60 seconds and “off” for 30 seconds) that repeats 5 times results in a hard mask thickness of 106.4 Å. In one or more examples, the lower temperature (e.g., 50° C.) allows for a slower etch process with a reduced amount of damage to the surrounding areas of the semiconductor device structure 400 (e.g., the dielectric layer 404). In one or more embodiments, operation 304 continues (e.g., the process gas will flow into the processing chamber and microwave energy will be delivered to the process gas) until the hard mask 408 is etched away or etched to a desired amount. In one or more embodiments, operation 304 continues so that the etch process continues within the semiconductor device structure 400 (e.g., within the feature 406) such that the components or contaminants within the feature 406 are etched away. In one or more embodiments, the etching of the hard mask 408 allows for increased uniformity between the features disposed across a semiconductor.

In one or more embodiments, chlorine material (e.g., Cl₂) is disposed within the feature 406 during processing operations. For example, during formation of a Mo via, the precursor for the deposition is MoCl₅. After formation of the Mo via, a Cl residue remains in the Mo via. During operation 304, the microwave oxidation etch process effectively removes residual chlorine material from the feature 406 (e.g., the Mo via).

At operation 306, as shown in FIG. 4C, a preclean process is performed on the semiconductor device structure 400. The preclean process etches away the metal oxide layer 410 and exposes the metal layer 403. In one or more embodiments the metal oxide layer 410 is molybdenum oxide. The preclean process of operation 306 includes exposing the metal oxide layer 410 with a non-plasma H₂ microwave (MW) process. The H₂ generated may have the etchants dissociated to form relatively mild and gentle etchants, so as gradually etch the metal oxide layer 410 from the metal layer 403. The H₂ plasma etches the metal oxide layer 410.

The H₂ MW process is conducted by supplying a hydrogen containing gas to a processing chamber. Suitable examples of the hydrogen containing gas include H₂, H₂O, H₂O₂, and the like. In at least one embodiment, H₂ is flowed into a processing chamber at a flow rate of about 50 sccm to about 2,000 sccm. For example, about 100 sccm. The processing chamber is operated at a temperature of about 25° C. to about 400° C., a pressure of about 1 mTorr to about 100 Torr, such as about 40 mTorr, and a radio-frequency (RF) power of about 100 W to about 1,000 W, such as about 150 W, for about 60 seconds to about 300 seconds.

In one or more embodiments, operation 304 and operation 306 occur in the same processing chamber. For example, processing chambers 120, 122, 124, 126, 128, 130, or 132 as shown in FIG. 1. In one or more embodiments, operation 304 and operation 306 occur in different processing chambers. For example, processing chambers 120, 122, 124, 126, 128, 130, or 132 as shown in FIG. 1.

At operation 308, as shown in FIG. 4D, a first selective deposition process is performed over the semiconductor device structure 400. The first selective deposition process includes a deposition process, such as such as chemical vapor deposition (CVD), physical vapor deposition (PVD), or the like. The selectivity in the first selective deposition process may arise from differences in reactions of a deposition precursor of the first metal material. For example, MoCl₅ reacts with H₂ to form Mo and HCl. The reaction occurs on the metal surface within the feature 406 and causes the selective deposition of Mo over the metal layer 403. In another example, a deposition precursor such as a molybdenum-containing precursor, a tungsten-containing precursor, or a ruthenium-containing precursor, reacts preferentially with the exposed bottom surface 406b of the feature 406 due to the exposed surface of the metal layer 403. Thus, resulting in a faster growth rate of Mo, W, or Ru over the exposed surface of the metal layer 403 than the exposed sidewall surface(s) 406s of the dielectric layers 404. In one or more embodiments, the Mo, W, or Ru deposition results in a capping layer 412 with a semi-circle shape (e.g., s semi-circle or a bump). The capping layer 412 includes Mo, W, or Ru.

In one or more embodiments, the molybdenum-containing precursor used during the deposition process may be selected from molybdenum chlorides (e.g., MoClx [x=2-6]), molybdenum fluorides (MoF₆)). In some embodiments, the molybdenum chloride can be or include molybdenum (II) chloride, molybdenum (III) chloride, molybdenum (IV) chloride, molybdenum (V) chloride, molybdenum (IV) chloride, or a combination thereof. In particular embodiments, the molybdenum chloride precursor can be or include molybdenum (V) chloride that is molybdenum pentachloride (MoCl₅). Suitable examples of the metal containing precursor include Mo(NMe₂)₄, MoCl₅, MoF₆, molybdenum tetramethylheptane-3,5-dionato (Mo(thd)₃), Mo(CO)₆, and the like that are used to form a molybdenum containing layer.

In one example, the first selective deposition process includes a CVD process that includes injecting a molybdenum containing precursor (e.g., molybdenum pentachloride (MoCl₅)), hydrogen (H₂) and a carrier gas (e.g., argon (Ar)) into a processing chamber, while maintaining the semiconductor device structure 400 disposed within the processing chamber at a temperature in a range of about 300 to 450° C., such as 400° C. In some embodiments, an ampoule temperature of an ampoule that includes the molybdenum containing precursor, which positioned upstream of the processing chamber environment, is maintained at a lower temperature than the temperature within the processing chamber. For example, the ampoule temperature may be maintained in a range of about 60 to 90° C. In certain embodiments, a pressure within the processing chamber during the deposition process may be maintained in a range of about 3 Torr to about 300 Torr. In certain embodiments, during the deposition process hydrogen (H₂) gas may be supplied at a flow rate of between about 500 sccm and about 15000 sccm, the carrier gas may be supplied at a flow rate of between about 0 sccm and about 1000 sccm, and the molybdenum containing precursor may be supplied at a flow rate. In one or more embodiments, the molybdenum containing precursor is pulsed into the chamber. In one or more embodiments, the first selective deposition process of operation 308 is repeated as needed to obtain the desired thickness of the capping layer 412. For example, the selective deposition process is repeated until the capping layer 412 is about 20 Å to about 40 Å.

At operation 310, as shown in FIG. 4E, further processing is performed on the semiconductor device structure 400 to form an electrical contact. The method further includes deposition of a passivation layer, a barrier layer deposition, removal of the passivation layer, and a metal fill process. FIG. 4E shows an example of a completed electrical contact after a metal fill process.

In one or more embodiments, the passivation layer is deposited over the capping layer 412 such that it covers the capping layer 412 with a second selective deposition process. The passivation layer may be formed of a self-assembled monolayer (SAM) of organic molecules. In one example, the SAM may comprise any suitable material such as, but not limited to, include thiols, silanes, phosphonates, alkyne, alkene, imidazole, or combinations thereof. In one example, the passivation layer may be formed using any suitable selective deposition process, such as a soaking process, spin-on process, chemical vapor deposition (CVD), or other similar process. The passivation layer deposition process may be performed in a processing chamber, such as the processing chamber 120, 122, 124, 126, 128, 130, or 132 shown in FIG. 1. In the soaking process, the semiconductor device structure 400 is exposed to a gas precursor including an unsaturated hydrocarbon, at a temperature of less than about 450° C. and a pressure of less than about 80 Torr for a time duration of greater than about 1 second with a flow rate of the precursor of between 50 sccm and about 600 sccm. In some embodiments, a liquid precursor is used in the soaking process. In the soaking process, organic molecules in the precursor are absorbed only on a metal surface, such as the exposed surface of the metal layer 403. The passivation layer may act as a block layer that suppresses nucleation or growth of a subsequent material deposition thereon. For example, the passivation layer is a block layer that suppresses nucleation or growth of a barrier layer such as tantalum nitride (TaN) or doped tantalum nitride (TaN). In an example, the processing chamber is operated at a temperature of about 300° C. to about 400° C. such as 350° C., SAM material is flowed into the processing chamber at a flow rate of about 100 sccm to about 1000 sccm such as 480 sccm, and the pressure is about 1 Torr to about 50 Torr such as 30 Torr. The SAM material is flowed into the processing chamber for about 200 seconds.

In one or more embodiments, a barrier layer is deposited within the feature 406 such that the barrier layer is selectively deposited over the sidewall surface(s) 406s. The passivation layer prevents the deposition of the barrier layer over the bottom surface 406b of the feature 406. In one or more embodiments, the barrier layer is about 10 Å. The selective deposition process can include a plasma enhanced CVD (PECVD) process in which a precursor gas (e.g., NH₃ or a metal containing precursor gas (e.g., TiCl₄, WF₆, WCl₅, or WCl₆)) and carrier gas (e.g., He, H₂, Ar, or N₂) are provided to the surface of the substrate disposed in the processing chamber. The barrier layer may be formed of tantalum nitride (TaN) or doped tantalum nitride (TaN), metal doped TaN, titanium nitride (TiN), tungsten nitride (WN), or tungsten nitride carbide (WCN). In an example, the processing chamber is operated at a temperature of about 200° C. to about 400° C. such as 250° C., NH₃ is flowed into the processing chamber at a flow rate of about 1000 sccm to about 1500 sccm such as 1200 sccm, and the pressure is about 1 mTorr to about 15 mTorr such as 2 mTorr. The process gas is pulsed into the chamber for about 36 cycles where each cycle is 1 second, 1 second, 4 seconds, 1 second.

In one or more embodiments, the passivation layer is removed with an etch process after the second selective deposition process. In one or more embodiments, the feature 406 is at least partially filled with a metal fill material 414 by use of a third selective deposition process (e.g., a selective bottom-up deposition process), as shown in FIG. 4E. The metal fill material 414 may be formed by any suitable deposition process such as an atomic layer deposition (ALD) process, a chemical vapor deposition (CVD) process, a hybrid ALD/CVD process, a plasma enhanced ALD (PEALD) process, a plasma enhanced CVD (PECVD) process, or the like. In some embodiments, the metal fill material includes molybdenum (Mo). In other embodiments, the metal fill material can be a metal such as tungsten (W), cobalt (Co), copper (Cu), ruthenium (Ru), or other useful metals. For example, a conventional CVD approach using a processing chamber (e.g., processing chambers 120, 122, 124, 126, 128, 130, or 132 shown in FIG. 1) includes a processing chamber temperature of about 400 C, the processing gases (e.g., MoCl₅ and H₂) to be flowed into the chamber at about 500 sccm to about 12000 sccm, the processing chamber includes a pressure of about 50 Torr, and the process occurs for about 60 minutes. The metal fill material 414 is deposited such that the metal fill material 414 contacts the capping layer 412. After the third selective deposition process, the semiconductor device structure 400 may be planarized, by used of a chemical mechanical planarization process.

Embodiments of the present disclosure generally relate to non-plasma methods of processing a substrate. More specifically, the methods disclosed herein incorporate microwave oxidation that is used to selectively etch materials during semiconductor device manufacturing. During processing, a hard mask such as a tungsten carbide (WC) hard mask may form over at least a portion of the feature. During a first selective deposition process of Mo, a Mo layer may form over the hard mask. When this occurs additional processing steps occur to remove the Mo layer and the hard mask, which increases throughput time, increases costs, and may damage the semiconductor device structure. Thus, removal of the hard mask early processing is beneficial. A selective etching process that utilizes microwave enhanced non-plasma processing methods is used to remove the WC hard mask before further processing. This allows for improved Mo selectivity during the first selective deposition process, prevents damage from surrounded layers (e.g., the dielectric layers), improves throughput of the process, and lowers the cost of the integration. Further, the methods disclosed herein are applicable in any FEOL or MOL process where a hard mask forms. Overall, the use of microwave enhanced non-plasma processing methods provides an alternative to wet etching that is beneficial in semiconductor manufacturing.

While the foregoing is directed to embodiments of the present disclosure, other and further embodiments of the disclosure may be devised without departing from the basic scope thereof, and the scope thereof is determined by the claims that follow.

What is claimed is:

1. A method for etching a semiconductor device structure, the method comprising:
performing a microwave oxidation etch process on the semiconductor device structure, wherein a hard mask is disposed over at least a portion of the semiconductor device structure, the microwave oxidation etch process comprising:
flowing a first process gas over the semiconductor device structure; and
delivering a microwave energy to the first process gas without generating a plasma; and
performing a preclean process on the semiconductor device structure, the preclean process comprising:
flowing a second process gas over the semiconductor device structure.

2. The method of claim 1, wherein the semiconductor device structure comprises:
a substrate,
at least one dielectric layer, wherein the dielectric layer is patterned to form at least one feature;
an etch stop layer disposed between the substrate and the at least one dielectric layer; and
a metal layer, wherein the metal layer is disposed within the at least one feature.

3. The method of claim 2, wherein the hard mask is disposed over an upper surface of the at least one feature.

4. The method of claim 1, wherein the first process gas is O₂.

5. The method of claim 1, wherein the microwave oxidation etch process selectively etches away the hard mask.

6. The method of claim 1, wherein the microwave oxidation etch process occurs in a process chamber with a temperature of about 350° C., a pressure of about 2 mT to about 10 mT, and a continuous flow of the first process gas at about 10 sccm for about 300 seconds.

7. The method of claim 1, wherein the second process gas is H₂.

8. The method of claim 1, wherein the preclean process etches away a metal oxide layer.

9. A method of filling a semiconductor device structure, the method comprising:
performing a microwave oxidation etch process on the semiconductor device structure, wherein the microwave oxidation etch process comprises flowing a first process gas over the semiconductor device structure, and delivering a microwave energy to the first process gas without generating a plasma, and wherein the semiconductor device structure comprises:
a substrate;
at least one dielectric layer, wherein at least one feature is patterned in the at least one dielectric layer, the at least one feature comprising an upper surface, a plurality of sidewall surfaces, and a bottom surface;
an etch stop layer disposed between the substrate and the at least one dielectric layer;
a metal layer disposed within the at least one feature;
a hard mask disposed over at least the upper surface of the feature; and
a metal oxide layer disposed over the bottom surface of the feature;
performing a preclean process on the semiconductor device structure, the preclean process comprising:
flowing a second process gas over the at least one feature; and
performing a selective deposition of a capping layer within the at least one feature, the capping layer disposed over the metal layer.

10. The method of claim 9, wherein the first process gas is O₂.

11. The method of claim 9, wherein the microwave oxidation etch process selectively etches away the hard mask.

12. The method of claim 9, wherein the microwave oxidation etch process occurs in a process chamber with a temperature of about 350° C., a pressure of about 2 mT to about 10 mT, and a continuous flow of the first process gas at about 10 sccm for about 300 seconds.

13. The method of claim 9, wherein the second process gas is H₂.

14. The method of claim 9, wherein the preclean process etches away the metal oxide layer such that the metal layer is exposed.

15. The method of claim 9, wherein the capping layer comprises molybdenum (Mo).

16. The method of claim 9, the selective deposition of the capping layer further comprising:
coflowing a third process gas comprising molybdenum pentachloride (MoCl₅)), a hydrogen (H₂) gas and a carrier gas comprising argon (Ar) over the at least one feature;
maintaining a temperature of a processing chamber at about 400° C.;
maintaining a pressure of the processing chamber at about 3 Torr to about 300 Torr; and
repeating the selective deposition of the capping layer to form the capping layer with a thickness of about 20 Å to about 40 Å.

17. A method of filling a semiconductor device structure, the method comprising:
performing a microwave oxidation etch process on the semiconductor device structure comprising at least one feature formed in a dielectric layer of the semiconductor device structure, wherein a hard mask is disposed over at least a portion of the semiconductor device structure, the microwave oxidation etch process comprising:
flowing a first process gas over the at least one feature;
delivering a microwave energy to the first process gas without generating a plasma;
performing a preclean process on the semiconductor device structure, the preclean process comprising:
flowing a second process gas over the at least one feature;
performing a selective deposition of a capping layer, the capping layer disposed within the at least one feature; and
depositing a metal fill material over the capping layer to fill the at least one feature.

18. The method of claim 17, wherein the first process gas is O₂.

19. The method of claim 17, wherein the microwave oxidation etch process selectively etches away the hard mask.

20. The method of claim 17, wherein the microwave oxidation etch process occurs in a process chamber with a temperature of about 350° C., a pressure of about 2 mT to about 10 mT, and a continuous flow of the first process gas at about 10 sccm for about 300 seconds.
